(19) United States
(12) Patent Application Publication
(10) Pub. No.: US 2025/0389281 A1
(43) Pub. Date: Dec. 25, 2025

(54) REFRIGERANT CIRCULATION DEVICE

(71) Applicant: NIDEC CORPORATION, Kyoto (JP)

(72) Inventors: Toshihiko TOKESHI, Kyoto (JP); Shinsuke HAMANO, Kyoto (JP); Taku MURAKAMI, Kyoto (JP); Tomoaki ANDO, Kyoto (JP); Takehito TAMAOKA, Kyoto (JP); Yu TACHIBANA, Kyoto (JP)

(21) Appl. No.: 19/245,682

(22) Filed: Jun. 23, 2025

Related U.S. Application Data
(60) Provisional application No. 63/663,229, filed on Jun. 24, 2024.

(30) Foreign Application Priority Data
Apr. 28, 2025 (JP) 2025-074826

(51) Int. Cl. F04D 29/60; F04D 25/16; F04D 27/00; H05K 7/20

(52) U.S. Cl. CPC F04D 29/601; F04D 25/16; F04D 27/001; H05K 7/20272

(57) ABSTRACT

A refrigerant circulation device includes a housing including a flow path through which a refrigerant is distributable, a pump assembly to be inserted into and pulled out from the housing, and a panel that is located on the housing and includes a display. The panel is movable between a first position where the panel overlaps with the pump assembly and a second position where the panel does not overlap with the pump assembly in an insertion/removal direction of the pump assembly.

### CROSS-REFERENCE TO RELATED APPLICATIONS

The present invention claims priority to US Provisional Patent Application No. 63/663,229 filed on Jun. 24, 2024, the entire contents of which are hereby incorporated herein by reference.

### 1. FIELD OF THE INVENTION

The present disclosure relates to refrigerant circulation devices.

### 2. BACKGROUND

Conventionally, there is known a refrigerant circulation device that cools a heat source such as a central processing unit (CPU) by transmitting heat received from the heat source to a circulating refrigerant. Conventionally, a configuration of a refrigerant circulation device which includes a plurality of pumps in a housing in a manner in which the plurality of pumps can be inserted and pulled out from a front surface side of the housing is known.

However, since the area of the pumps occupying the housing front surface is large in such a conventional refrigerant circulation device, it is difficult to secure a space for disposing a monitor even if it is attempted to dispose a monitor to display operating conditions of the refrigerant circulation device, for example, on the housing front surface where users can easily view the monitor.

### SUMMARY

A refrigerant circulation device according to an example embodiment of the present disclosure includes a housing including a flow path through which a refrigerant is distributable, a pump assembly to be inserted into and pulled out from the housing, and a panel that is located on the housing and includes a display. The panel is movable between a first position where the panel overlaps with the pump assembly and a second position where the panel does not overlap with the pump assembly in an insertion/removal direction of the pump assembly.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic perspective view of a CDU according to an example embodiment of the present disclosure.

FIG. 2 is a schematic perspective view illustrating an inside of a CDU according to an example embodiment of the present disclosure.

FIG. 3 is a schematic front view of a CDU according to an example embodiment of the present disclosure.

FIG. 4 is a schematic side view of a CDU according to an example embodiment of the present disclosure.

FIG. 5 is an overview configuration diagram of a CDU according to an example embodiment of the present disclosure.

FIG. 6A is a perspective view illustrating a pump assembly according to an example embodiment of the present disclosure.

FIG. 6B is a perspective sectional view illustrating a fitting portion between a pump assembly and a housing according to an example embodiment of the present disclosure.

FIG. 7A is a perspective sectional view illustrating a handle operating portion of a pump assembly according to an example embodiment of the present disclosure.

FIG. 7B is a perspective sectional view illustrating a restriction state of a pump assembly according to an example embodiment of the present disclosure.

FIG. 8 is a perspective view illustrating a front surface of a CDU according to an example embodiment of the present disclosure.

FIG. 9 is a perspective view illustrating a front surface of a CDU according to an example embodiment of the present disclosure.

FIG. 10 is a plan view illustrating a panel and a pump assembly of a CDU according to an example embodiment of the present disclosure.

FIG. 11 is a perspective enlarged view illustrating a front surface of a CDU according to an example embodiment of the present disclosure.

FIG. 12 is a perspective view illustrating a configuration of a locking portion according to an example embodiment of the present disclosure.

FIG. 13 is a perspective view illustrating a configuration of a locking portion according to an example embodiment of the present disclosure.

FIG. 14 is a front view of a CDU according to an example embodiment of the present disclosure.

FIG. 15 is a perspective enlarged view illustrating a panel and peripheral members thereof according to an example embodiment of the present disclosure.

FIG. 16 is a sectional view along the line XVI-XVI in FIG. 4.

FIG. 17 is a sectional view along the line XVII-XVII in FIG. 4.

FIG. 18 is a sectional view along the line XVIII-XVIII in FIG. 4.

FIG. 19 is a sectional view along the line XIX-XIX in FIG. 4.

### DETAILED DESCRIPTION

Hereinafter, refrigerant circulation devices according to example embodiments of the present disclosure will be described in detail with reference to the drawings. Note that the example embodiments do not limit the present disclosure. Also, the example embodiments can be appropriately combined without causing contradiction of processing content. In the following example embodiments, the same components will be denoted by the same reference signs, and repeated description will be omitted.

Each of the drawings to be referred to below may define an X axis direction, a Y axis direction, and a Z axis direction orthogonal to one another, and may show an orthogonal coordinate system, in which the positive Z axis direction is a vertically upward direction, for easy understanding of the description.

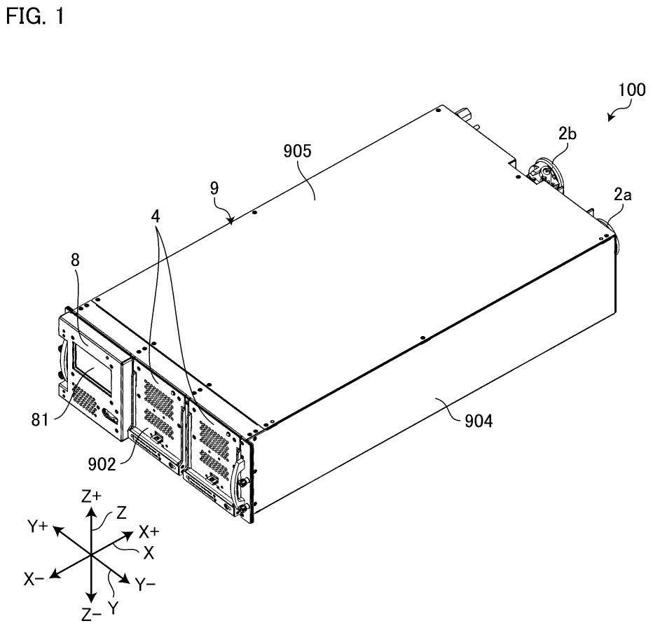

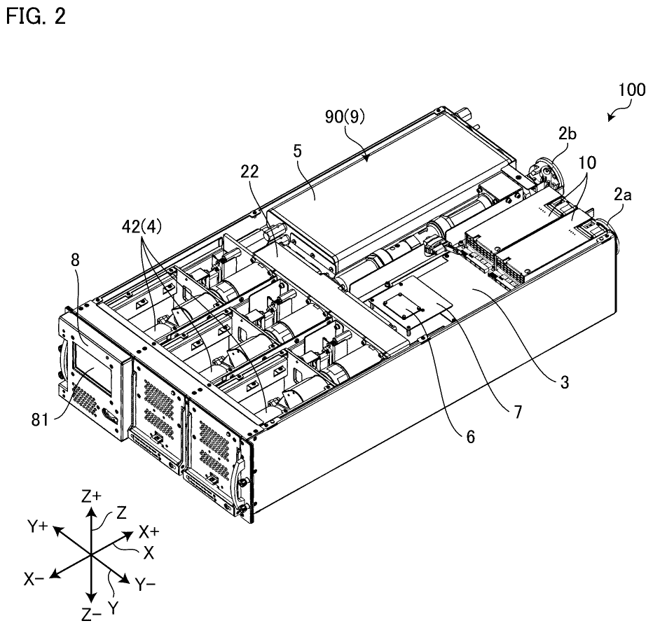

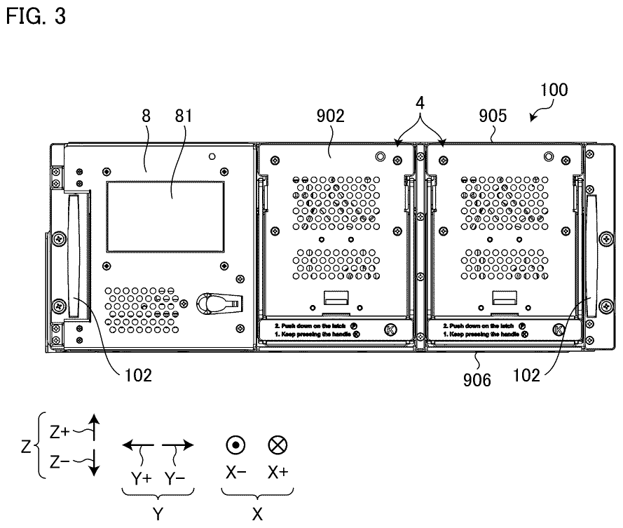

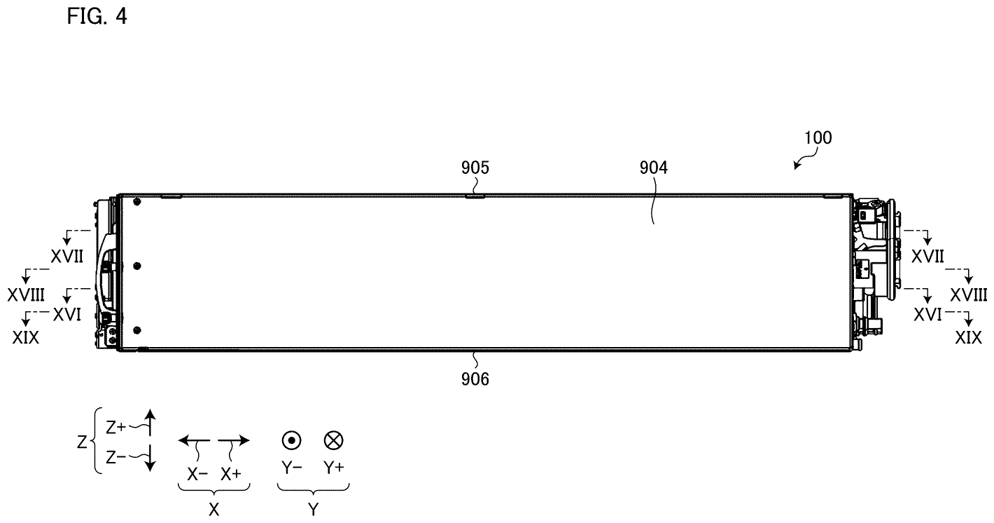

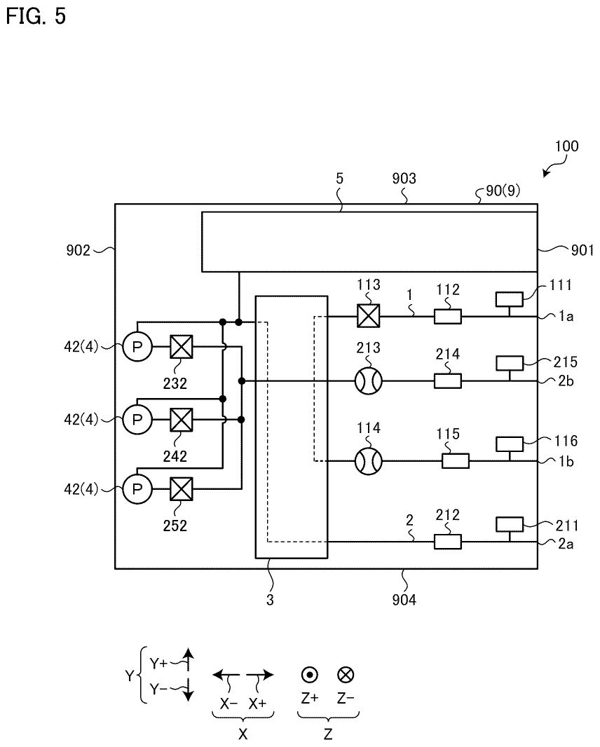

Next, a configuration of a CDU 100 according to an embodiment will be described with reference to FIGS. 1 to 5. FIG. 1 is a schematic perspective view of the CDU 100 according to the example embodiment. FIG. 2 is a schematic perspective view illustrating the inside of the CDU 100 according to the example embodiment. FIG. 3 is a schematic front view of the CDU 100 according to the example embodiment. FIG. 4 is a schematic side view of the CDU 100 according to the example embodiment. FIG. 5 is an overview configuration diagram of the CDU 100 according to the example embodiment. The term “CDU” is an abbreviation for “coolant distribution unit”. The CDU 100 is an example of a refrigerant circulation device.

The CDU 100 controls a flow rate, a temperature, water quality, or a distribution destination of a refrigerant supplied from an equipment side. The CDU 100 sucks a primary refrigerant to the inside of the CDU 100 and pumps the primary refrigerant to the outside of the CDU 100. The CDU 100 also sucks a secondary refrigerant to the inside of the CDU 100 and pumps the secondary refrigerant to the outside of the CDU 100.

The CDU 100 performs heat exchange between the primary refrigerant and the secondary refrigerant. For example, refrigerants such as an antifreeze and pure water can be used as the primary refrigerant and the secondary refrigerant. Examples of the antifreeze usable as a refrigerant include an ethylene glycol aqueous solution and a propylene glycol aqueous solution. The primary refrigerant and the secondary refrigerant may be identical in type to each other or different in type from each other. At least one of the primary refrigerant and the secondary refrigerant may be a gas refrigerant.

The CDU 100 includes a primary flow path 1 (see FIG. 5), a secondary flow path 2 (see FIG. 5), a heat exchanger 3, a pump assembly 4, a tank 5, a control unit 6, a wiring substrate 7, a panel 8, power supplies 10, and control valves 113, 232, 242, and 252 (see FIG. 5). The primary refrigerant is distributed through the primary flow path 1. The secondary refrigerant is distributed through the secondary flow path 2. The primary flow path 1 and the secondary flow path 2 are examples of the flow paths. Details of the primary flow path 1 and the secondary flow path 2 will be described later.

The heat exchanger 3 is connected to the primary flow path 1 and the secondary flow path 2. The primary refrigerant and the secondary refrigerant flow into the heat exchanger 3 and flow out of the inside of the heat exchanger 3. The heat exchanger 3 exchanges heat between the primary refrigerant and the secondary refrigerant therein. The heat exchange system of the heat exchanger 3 is a plate system, for example. The outer peripheral surface of the heat exchanger 3 is covered with a heat insulating material. The tank 5, the control unit 6, the wiring substrate 7, and the power supplies 10 are disposed on the heat exchanger 3 via a heat insulating material.

The pump assembly 4 is connected to the secondary flow path 2. The pump assembly 4 has an internal flow path. When the pump assembly 4 is driven, the secondary refrigerant is sucked into the internal flow path of the pump assembly 4, and the secondary refrigerant is pumped from the internal flow path of the pump assembly 4. In this manner, the secondary refrigerant circulates between the CDU 100 and an external cold plate. The number of pump assemblies 4 installed is not particularly limited. For example, the number of pump assemblies 4 installed is three. In other words, the CDU 100 may include a plurality of pump assemblies 4. The plurality of pump assemblies 4 may all have the same configuration and a common design. It is thus possible to improve productivity of the pump assemblies 4, and there is no concern that the pump assemblies 4 will be inserted into wrong positions. Also, the panel 8, which will be described later, may be located on the negative side of the X axis as compared with the plurality of pump assemblies 4. As a result, it is possible to use the same three pump assemblies 4, to align couplers on a collection manifold 22 in the Y axis direction (at the same positions in the X axis direction), to place insertion ports of the pump assemblies 4 in the same plane, and to thereby improve productivity. The configuration of each pump assembly 4 will be described later.

The tank 5 stores the refrigerant used as the secondary The tank 5 is connected to the secondary flow path refrigerant. 2. The tank 5 can supply the refrigerant to the secondary flow path 2. In a case where the secondary refrigerant circulating in the secondary flow path 2 decreases, the flow rate of the circulating secondary refrigerant can be kept constant by causing the refrigerant stored in the tank 5 to flow into the secondary flow path 2.

The tank 5 includes a liquid level sensor (not illustrated), an inspection window (not illustrated) through which a liquid level can be visually checked, an air vent valve (not illustrated) that releases gas accumulated in the tank 5, and a water injection hole (not illustrated) through which the refrigerant can be injected into the tank 5 when the refrigerant decreases.

The control unit 6 controls sensors 111, 112, 114 to 116, 211, 212, 214, and 215, a pump 42, control valves 113, 232, 242, and 253 (see FIG. 5), and the like disposed in the CDU 100, and monitors the status.

The panel 8 includes a display 81. The display 81 displays an operating condition of the system, measured values of the sensors 111, 112, 114 to 116, 211, 212, 214, and 215, and the like. The configuration of the panel 8 will be described later.

The power supplies 10 supply power to the pump 42, the control valves 113, 232, 242, and 253 (see FIG. 5), and the like. Two power supplies 10 are disposed on the side of a first surface 901 of the CDU 100.

The control valves 113, 232, 242, and 253 (see FIG. 5) control the flow rate of the refrigerant by controlling opening and closing of the valves.

The CDU 100 includes a housing 9. The housing 9 has an accommodation region 90. The housing 9 accommodates, in the accommodation region 90, the primary flow path 1, the secondary flow path 2, the heat exchanger 3, the pump assembly 4, the tank 5, the control unit 6, the wiring substrate 7, the power supplies 10, and the control valves 113, 232, 242, and 253.

Note that FIGS. 2 and 5 illustrate an example of the configuration of the CDU 100 and members other than the members illustrated in FIGS. 2 and 5 may be further included.

Next, the housing 9 of the CDU 100 according to the example embodiment will be described with reference to FIGS. 1 to 5.

The accommodation region 90 of the housing 9 has a substantially rectangular shape with the X axis direction as a long-side direction and the Y axis direction as a short-side direction in plan view from the Z axis direction. In other words, the accommodation region 90 extends in the X axis direction and the Y axis direction intersecting each other, and has a longer dimension in the X axis direction than in the Y axis direction. In the accommodation region 90, the Z axis direction is a depth direction. The width (depth) of the accommodation region 90 in the Z axis direction smaller than the widths of the accommodation region 90 in the X axis direction and the Y axis direction.

The housing 9 includes a first surface 901 to a sixth surface 906. The first surface 901 to the sixth surface 906 surround the accommodation region 90. In other words, the housing 9 has a region surrounded by the first surface 901 to the sixth surface 906 as the accommodation region 90.

The first surface 901 and the second surface 902 are disposed to face each other in the X axis direction with the accommodation region 90 interposed therebetween. The first surface 901 is disposed on one side in the X axis direction (on the positive side of the X axis). The second surface 902 is disposed on the other side in the X axis direction (on the negative side of the X axis). In the following description, the first surface 901 may be referred to as a rear surface 901, and the second surface 902 may be referred to as a front surface 902.

As illustrated in FIG. 5, the first surface 901 is provided with a primary inlet port 1a and a primary outlet port 1b for the primary refrigerant, and a secondary inlet port 2a and a secondary outlet port 2b for the secondary refrigerant. As illustrated in FIG. 3, the second surface 902 is provided with a front handle 102. The front handle 102 is exposed in a front view in a state where the panel 8 is closed. As a result, the front handle 102 can be used in the state where the panel 8 is closed.

The third surface 903 and the fourth surface 904 are disposed to face each other in the Y axis direction with the accommodation region 90 interposed therebetween. The third surface 903 is disposed on one side in the Y axis direction (on the positive side of the Y axis). The fourth surface 904 is disposed on the other side in the Y axis direction (on the negative side of the Y axis).

The fifth surface 905 and the sixth surface 906 are disposed to face each other in the Z axis direction with the accommodation region 90 interposed therebetween. The fifth surface 905 is disposed on one side in the Z axis direction (on the positive side of the Z axis). The sixth surface 906 is disposed on the other side in the Z axis direction (on the negative side of the Z axis).

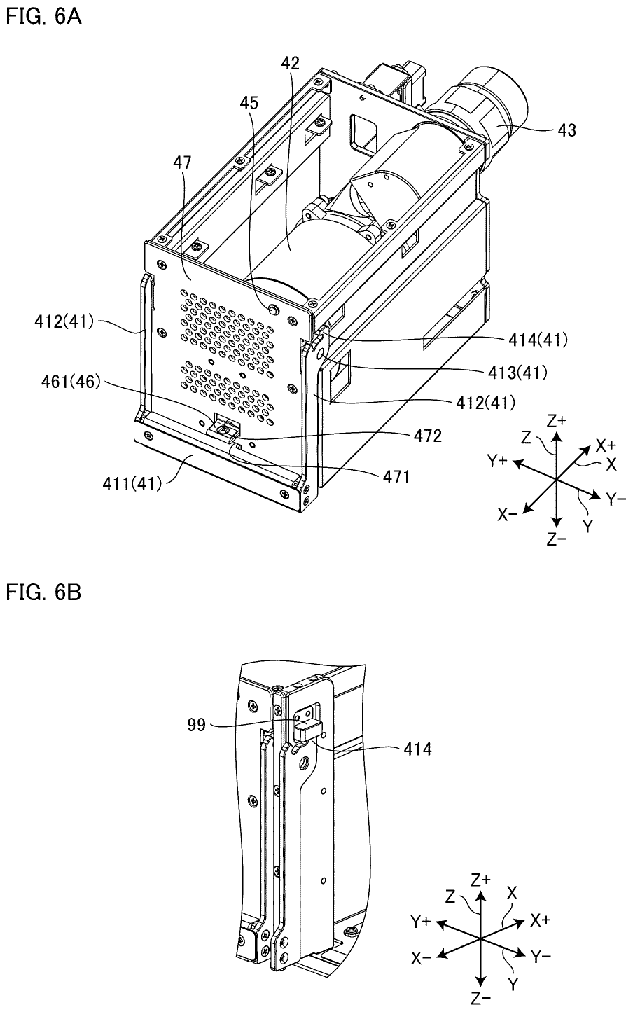

Next, the pump assembly 4 according to the example embodiment will be described with reference to FIG. 6A. FIG. 6A is a perspective view illustrating a pump assembly 4 according to the example embodiment.

The pump assemblies 4 can be inserted into and pulled out from the housing 9 of the CDU 100. Each pump assembly 4 includes a handle 41, a pump 42, a coupling 43, and a control board (not illustrated). Since the pump 42 and the CDU 100 are connected via the coupling 43, it is possible to suppress leakage of the refrigerant when the pump assembly 4 is inserted and pulled out. The coupling 43 includes a first member (not illustrated) that can be connected to the pump 42 and a second member (not illustrated) that is fixed to the CDU 100. The refrigerant can be distributed between the CDU 100 and the pump 42 by the first member and the second member being connected to each other.

Even in a case where the refrigerant leaks due to a connection failure of the coupling 43, it is possible to suppress the refrigerant spreading to the outside of the device of the CDU 100 by providing a liquid receiving dish (not illustrated) below the connecting portion of the coupling 43. Since the connection failure of the coupling 43 occurs due to the pump assembly 4 obliquely moving when the pump assembly 4 is inserted or pulled out, a guide rail (not illustrated) to cause the pump assembly 4 to move straight is provided. Such a guide rail may be provided only on the lower surface of the pump assembly 4 or may be provided only on the upper surface thereof. Also, guide rails may be provided on both the upper surface and the lower surface of the pump assembly 4. Each guide rail may be inclined at an opening portion for the pump assembly 4 such that the opening expands. This facilitates insertion of the pump assembly 4 into the CDU 100.

It is possible to connect the pump assembly 4 with small deviation thereof absorbed by providing a floating mechanism in the second member of the coupling 43.

The control board of the pump assembly 4 may be disposed on the side further upward than the pump 42. It is thus possible to curb breakdown due to the refrigerant even in a case where liquid leakage from the pump 42 occurs.

The pump assembly 4 may include a resin cover (not illustrated) that protects the control board and the wiring.

Since the upper portion of the sixth surface 906 of the CDU 100 that is in contact with the lower surface of the pump assembly 4 is formed of a resin plate, the pump assembly 4 can be inserted and pulled out with small friction. Examples of the type of the plate include PTFE and PFA.

The three pump assemblies 4 can increase the flow rate of the secondary refrigerant pumped from the CDU 100 by simultaneously operating the three pumps 42. In a case where required cooling performance can be achieved by a flow rate smaller than the flow rate at which all the three pump assemblies 4 are operated, it is possible to operate two pumps 42 or one pump 42 while causing the rest of the pumps 42 to stop operating.

In an example case where only two pumps 42 are operated while one pump 42 is stopped, it is possible to switch the pumps 42 to be operated depending on an operation time such that the operation times of the pump assemblies 4 become uniform. Therefore, it is possible to curb unevenness of the operation times of the pumps 42. In a case where the pumps 42 are not operated for a long period of time, sticking may occur in movable parts such as impellers and may lead to breakdown, and it is thus possible to curb breakdown of the pumps 42 by periodically operating them to prevent sticking. Even in a case where an operating pump 42 has caused breakdown, it is possible to stop the operation of the pump 42 having caused the breakdown and to cause another pump 42 that has stopped to operate and thereby to curb a decrease in flow rate of the circulation regardless of the one pump 42 having caused the breakdown. In addition, it is possible to facilitate replacement of the pumps 42 and to improve maintainability of the pumps 42 by using hot swappable pumps 42.

Each pump assembly 4 may include an indicator lamp 45 that displays an operating condition of the pump assembly 4 on a front surface 47 along the insertion/removal direction (X axis direction). The indicator lamp 45 may display the status (normal, breakdown, a failure of connection to the power supply 10, and the like) of the pump assembly 4. The status of the pump 42 can be easily checked through the indicator lamp 45.

Although FIG. 6A illustrates an example where the number of indicator lamps 45 is one, it is possible to provide a plurality of indicator lamps 45. In addition, the status of the pump 42 can be identified by a blinking method or a blinking color of the indicator lamp 45.

Next, the handle 41 of the pump assembly 4 according to the example embodiment will be described with further reference to FIG. 6B. FIG. 6B is a perspective sectional view illustrating a fitting portion between the pump assembly 4 and the housing 9 according to the example embodiment.

The handle 41 is rotatably fixed to both side surfaces perpendicularly intersecting the insertion/removal direction (X axis direction) of the pump assembly 4, is located on the front surface 47 along the insertion/removal direction of the pump assembly 4, and projects in a direction apart from the housing 9 beyond the front surface 47 (the negative direction of the X axis).

Specifically, the handle 41 includes a handle operating portion 411, two handle side portions 412, rotation support portions 413, and a facing portion 414. The handle operating portion 411 is located outside the housing 9 in a state where the pump assembly 4 is inserted into the housing 9. The handle operating portion 411 may be provided with display of operation content. It is thus possible to curb operational errors of a user. As illustrated in FIG. 3, the panel 8 does not overlap the handle operating portion 411 of the pump assembly 4 next to the panel 8 in a front view in a state where the panel 8 is closed.

The two handle side portions 412 are located on both the side surfaces of the pump assembly 4. Each handle side portion 412 has one end portion connected to the handle operating portion 411 and the other end portion fixed to the side surface of the pump assembly 4 by the rotation support portions 413. In other words, the handle operating portion 411 couples the two handle side portions 412. The other end portion of the handle side portion 412 is provided with the facing portion 414 facing a projecting portion 99 of the housing 9. The projecting portion 99 projects in a direction (Y axis direction) intersecting the insertion/removal direction of the pump assembly 4 from the surface of the housing 9 facing the side surface of the pump assembly 4.

The handle 41 is displaceable between a third position and a fourth position. Specifically, in a case where the handle 41 is at the third position, the two handle side portions 412 extend in the direction (X axis direction) perpendicularly intersecting the front surface 47 of the pump assembly 4, and at least a part of one end portion of each of the two handle side portions 412 is located on the side closer to the front surface (on the negative side of the X axis) than the front surface. Accordingly, the handle operating portion 411 is located on the side further forward (on the negative side of the X axis) than the front surface 47. On the other hand, in a case where the handle 41 is at the fourth position, the two handle side portions 412 extend along both the side surfaces of the pump assembly 4, and accordingly, the handle operating portion 411 is located at a lower portion of the front surface 47 in a front view on the side further forward (on the negative side of the X axis) than the front surface 47 as illustrated in FIG. 6A. In the case where the handle 41 is at the third position, the handle operating portion 411 is located further upward (on the positive side of the Z axis) than in the case where the handle 41 is at the fourth position. In other words, the handle 41 is in a raised state when the handle 41 is at the third position, and the handle 41 is in a lowered state when the handle 41 is at the fourth position. The handle 41 is displaceable between the third position and the fourth position by the rotation support portions 413 rotating the handle side portions 412 about a rotation axis extending along a direction (Y axis direction) intersecting the insertion/removal direction.

Next, a procedure of inserting the pump assembly 4 into the CDU 100 according to the example embodiment will be described.

First, insertion of the pump assembly 4 in a state where the handle 41 is raised, that is, in a state where the handle 41 is at the third position into the CDU 100 is started. Next, when the distance between the front surface 902 of the CDU 100 and the front surface 47 of the pump assembly 4 becomes a predetermine distance, for example, about 10 mm, the pump assembly 4 is pushed and inserted into the CDU 100 with the handle 41 lowered. At this time, the facing portion 414 of the handle 41 comes into contact with the projecting portion 99 of the housing 9 of the CDU 100. The pump assembly 4 is inserted with the projecting portion 99 caused to serve as a fulcrum by lowering the handle 41.

In a state where the handle 41 is fully lowered, that is, in a state where the handle 41 is at the fourth position, the facing portion 414 is located on the deeper side in the insertion direction (on the positive side of the X axis) of the pump assembly 4 than the projecting portion 99, a state where the facing portion 414 and the projecting portion 99 overlap with each other in the insertion/removal direction (X axis direction) of the pump assembly 4, that is, a facing state is achieved, and it thus becomes not possible to pull out the pump assembly 4 from the CDU 100.

The pump assembly 4 includes the two rotation support portions 413 to thereby curb deviation of the pump assembly 4 in the direction (Y direction) axis perpendicular to the insertion/removal direction due to a force applied only to one of the rotation support portions 413 by a handle operation when the handle 41 is lowered.

Next, a procedure of removing the pump assembly 4 according to the example embodiment will be described.

Next, an operation portion 461 is lowered and the handle 41 is raised with the handle 41 at the fourth position pressed. At this time, the handle 41 rotates about the rotation support portions 413, and the handle 41 moves from the fourth position to the third position by pulling the handle 41 toward the front side of the CDU 100. In this manner, a state where the facing portion 414 of the handle side portion 412 and the projecting portion 99 do not overlap in the insertion/removal direction (X axis direction) of the pump assembly 4, that is, in a state where they do not face each other is achieved, and it becomes possible to pull out the pump assembly 4 from the CDU 100. Note that the operation portion 461 will be described later.

When the handle 41 is fully raised, that is, when the handle 41 is at the third position, the pump assembly 4 is pulled out from the CDU 100 with the handle operating portion 411 held.

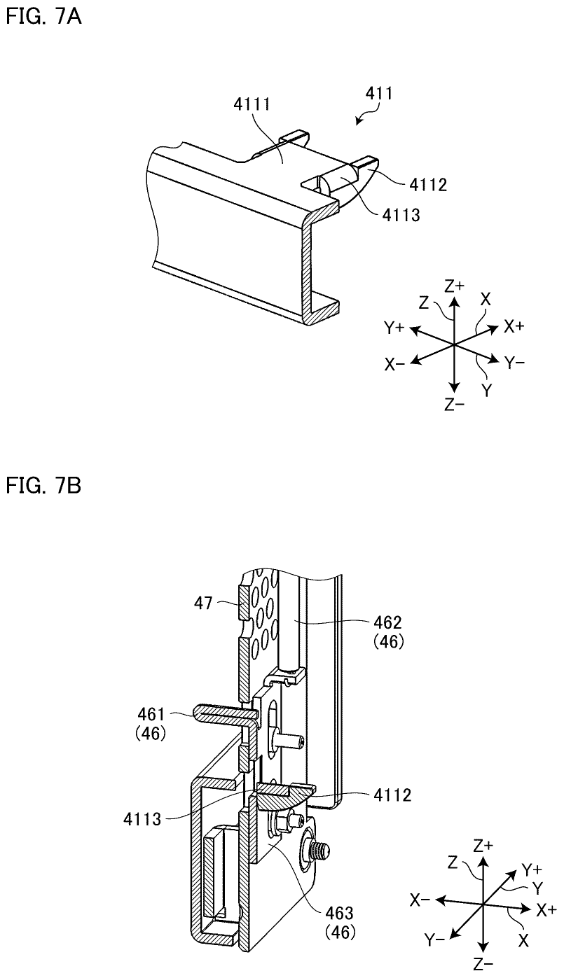

Next, restriction of movement of the pump assembly 4 according to the example embodiment will be described with further reference to FIGS. 7A and 7B. FIG. 7A is a perspective sectional view illustrating the handle operating portion 411 of the pump assembly 4 according to the example embodiment. FIG. 7B is a perspective sectional view illustrating a restriction state of the pump assembly 4 according to the example embodiment.

As illustrated in FIG. 6A and 7B, the pump assembly 4 includes a restriction portion 46 that restricts movement of the handle 41 to the third position when the handle 41 is located at the fourth position. In other words, the restriction portion 46 restricts the handle 41 not to move upward in the state where the handle 41 is lowered.

The restriction portion 46 includes the operation portion 461, an elastic member 462, and a plate portion 463. The operation portion 461 is displaceable between a fifth position and a sixth position. Specifically, a case where the operation portion 461 is at the fifth position is a case where the operation portion 461 is located on the positive side of the Z axis in a through-hole 472 in the front surface 47. A case where the operation portion 461 is at the sixth position is a case where the operation portion 461 is located on the negative side of the Z axis in the through-hole 472 in the front surface 47 as illustrated in FIG. 6A. In other words, the operation portion 461 is in a raised state when the operation portion 461 is at the fifth position, and the operation portion 461 is in a lowered state when the operation portion 461 is at the sixth position.

The elastic member 462 biases the operation portion 461 in a direction from the sixth position to the fifth position (in the positive direction of the Z axis). As illustrated in FIG. 7B, the plate portion 463 is connected to the operation portion 461 on the rear surface side of the front surface 47 of the pump assembly 4.

The restriction portion 46 restricts the movement of the handle 41 to the third position by the operation portion 461 moving from the sixth position to the fifth position along with the movement of the handle 41 from the third position to the fourth position. On the other hand, the state where the movement of the handle 41 to the third position is restricted is released in a case where the operation portion 461 moves from the fifth position to the sixth position.

In this manner, it is possible to curb pulling-out of the pump assembly 4 from the CDU 100 due to the handle 41 moving to the third position because of an erroneous operation, by the CDU 100 including the restriction portion 46. Since the restriction portion 46 includes the operation portion 461, the state of the restriction portion 46 can be changed by a user operation.

As illustrated in FIG. 7A, the handle operating portion 411 includes a penetration portion 4111 to be inserted into a through-hole 471 provided in the front surface 47 of the pump assembly 4. The penetration portion 4111 includes an inclined portion 4112 inclined in a direction in which the penetration portion 4111 is inserted into the through-hole 471 and a facing portion 4113 having no inclination.

When the handle 41 is lowered after the pump assembly 4 is inserted into the CDU 100, the penetration portion 4111 of the handle operating portion 411 is inserted into the through-hole 471, and the plate portion 463 and the facing portion 4113 face each other in the insertion/removal direction (X axis direction). Since the operation portion 461 and the plate portion 463 are pulled upward in the vertical direction (on the positive side of the Z axis) by the elastic member 462, at least a part of the plate portion 463 is brought into a state of being located at a position where the part faces the through-hole 471 (see FIG. 7B) unless the user lowers the operation portion 461. Therefore, the user is suppressed from raising the handle 41. In other words, the movement of the handle 41 to the third position is restricted.

In other words, in a case where the penetration portion 4111 penetrates through the through-hole 471, the facing portion 4113 and the plate portion 463 face each other in the insertion/removal direction, and therefore the penetration portion 4111 is prevented from coming off of the through-hole 471 unless the user lowers the operation portion 461.

When the user lowers the operation portion 461, the elastic member 462 extends and the plate portion 463 is also lowered and does not face the facing portion 4113, and therefore the penetration portion 4111 can be pulled out from the through-hole 471 and the handle 41 can be moved.

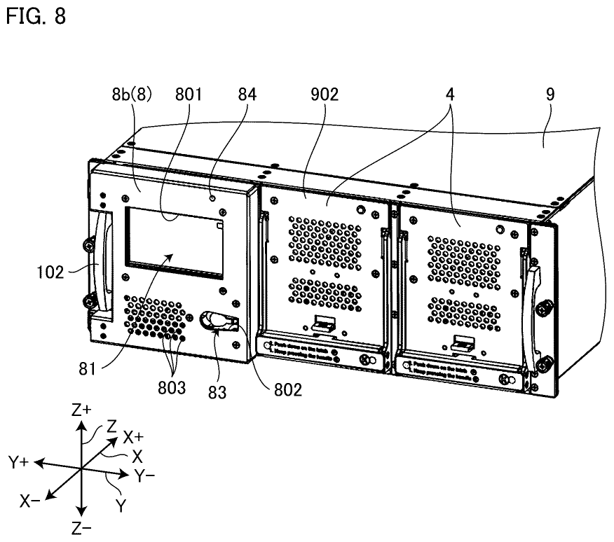

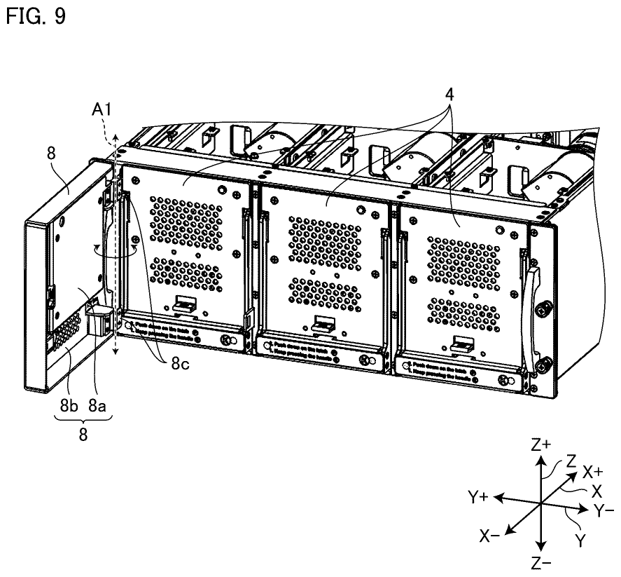

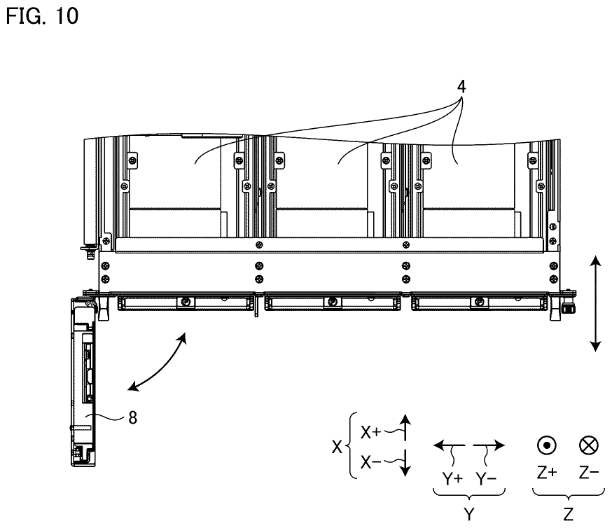

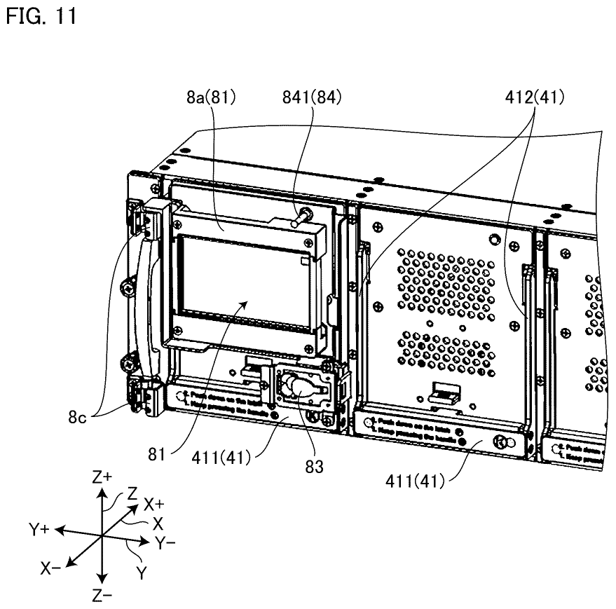

Next, the panel 8 and the display 81 according to the example embodiment will be described with reference to FIGS. 8 to 11. FIGS. 8 and 9 are perspective views illustrating the front surface 902 of the CDU 100 according to the example embodiment. FIG. 10 is a plan view illustrating the panel 8 and the pump assembly 4 of the CDU 100 according to the example embodiment. FIG. 11 is a perspective enlarged view illustrating the front surface 902 of the CDU 100 according to the example embodiment.

The panel 8 may include a first member 8a, a second member 8b, and a support portion 8c. The first member 8a includes the display 81.

The display 81 displays data such as operating conditions of the pump 42 or the control valves 113, 232, 242, and 252 and the refrigerant temperature acquired from the sensors 111, 112, 114 to 116, 211, 212, 214, and 215 (see FIG. 5).

The display 81 may include an operation surface that receives an operation by the user. The display 81 may be, for example, a touch panel display. The display 81 as the touch panel display is a flat panel display such as a liquid crystal display or an organic EL display, for example. The display 81 as the touch panel display can set a control method of the pump 42, for example, whether to perform control to lower the temperature at or below a dew point and whether to switch the operation of the pumps 42 depending on an operating time. In addition, the display 81 as the touch panel display can set an upper limit and a lower limit of the temperature of the secondary refrigerant, for example, the number of times the pump 42 is to be rotated and whether to adjust the amount of the primary refrigerant flowing into the heat exchanger 3 to cause the refrigerant temperature to fall within a set temperature range.

In this manner, the user can check the operating condition of the CDU 100 and perform various kinds of setting in accordance with the operating condition of each component in the CDU 100 by the display 81 including the operation surface.

The second member 8b is, for example, a cover member that covers the first member 8a. Specifically, the second member 8b includes a cover surface located at a position shifted from the first member 8a in a direction perpendicularly intersecting the display 81 and in a direction spaced apart from the housing 9 (the negative direction of the X axis) and side surfaces connected to the cover surface and extending in a direction perpendicularly intersecting the cover surface and in a direction closer to the housing 9 (the positive direction of the X axis). The cover surface is a surface facing the display 81. As illustrated in FIG. 9, the first member 8a is located in a space formed by such a cover surface and side surfaces.

The second member 8b includes an opening 801. The opening 801 has a rectangular shape and is provided at a position corresponding to the display 81 in the cover surface. Specifically, the size of the opening 801 may be larger than the size of the display 81. The opening 801 is located at a position where the opening 801 overlaps with the display 81 in the direction perpendicularly intersecting the display 81 of the panel 8 (X axis direction).

The second member 8b may further include an opening 802. The opening 802 is provided at a position corresponding to a locking portion 83, which will be described later, in the cover surface. The opening 802 is located at a position where the opening 802 overlaps with the locking portion 83 in the direction perpendicularly intersecting the display 81 of the panel 8 (X axis direction).

The dimension of the second member 8b in the vertical direction (Z axis direction) may be larger than the dimension of the first member 8a in the vertical direction (Z axis direction).

Here, the panel 8 of the CDU 100 according to the example embodiment is movable between a first position and a second position. In a case where the panel 8 is located at the first position, the panel 8 is located at a position where the panel 8 overlaps with the pump 4 in the insertion/removal direction (X axis direction) of the pump assembly 4 as illustrated in FIG. 8. In a case where the panel 8 is located at the second position, the panel 8 is located at a position where the panel 8 does not overlap with the pump 4 in the insertion/removal direction (X axis direction) of the pump assembly 4 as illustrated in FIGS. 9 and 10.

According to such a configuration, it is possible to dispose the pump assemblies 4 and the panel 8 with the display 81 even in a limited area. In addition, since both the pump assembly 4 and the display 81 can be disposed on the front surface 902 of the CDU 100, insertion and removal operations of the pump assembly 4 with respect to the CDU 100 and visual recognition of the display 81 are facilitated, and workability can thus be improved.

Specifically, the panel 8 may be supported to be rotatable about a rotation axis A1 at the front surface 902 of the CDU 100 by a support portion 82. The support portion 8c is, for example, a hinge. The panel 8 may include two support portions 8c. One of the two support portions 8c may be connected to the first member 8a of the panel 8, and the other may be connected to the second member 8b of the panel 8.

The panel 8 may be movable between the first position and the second position by being rotated about the rotation axis A1 extending in the vertical direction (Z axis direction) by the support portion 8c. In a case where the panel 8 is located at the first position, the panel 8 is located along the front surface 902 (the X axis direction and the Z axis direction) of the CDU 100 as illustrated in FIG. 8. In this case, since the panel 8 is disposed to overlap with the front surface 47 of the pump assembly 4 in the insertion/removal direction (X axis direction) of the pump assembly 4, the pump assembly 4 cannot be inserted into and removed from the CDU 100.

In a case where the panel 8 is located at the second position, the panel 8 is located along a direction intersecting the front surface 902 of the CDU 100. In this case, since the panel 8 is disposed so as not to overlap with the pump assembly 4 in the insertion/removal direction (X axis direction) of the pump assembly 4, the pump assembly 4 can be inserted into and pulled out from the CDU 100. In this case, since the operation of the rear surface of the second member 8b with the display 81 is facilitated, maintenance of the wiring (not illustrated) such as a communication cable for connection to the control unit 6 can be easily performed.

Furthermore, since the panel 8 is rotated about the rotation axis A1 by the support portion 8c, the CDU 100 can be disposed in a space-saving manner in the height direction (Z axis direction).

Note that although FIGS. 9 and 10 illustrates an example in which the panel 8 is positioned along the direction (Y axis direction) perpendicularly intersecting the front surface 902 of the CDU 100 when the panel 8 is located at the second position, that is, an example in which the panel 8 has rotated by about 90 degrees around the rotation axis A1 from the state where the panel 8 is located at the first position, the present disclosure is not limited thereto. The panel 8 may rotate by 90 degrees or more about the rotation axis A1 from the state where the panel 8 is at the first position. In other words, the second position of the panel 8 may be a position obtained by rotating the state where the panel 8 is at the first position by 90 degrees or more around the rotation axis A1.

Although the example in which the panel 8 is rotatable about the rotation axis A1 between the first position and the second position has been described here, the moving mode of the panel 8 is not limited to rotation. For example, the panel 8 may be movable between the first position and the second position by sliding.

The support portions 8c are disposed at positions at which the support portions 8c overlap the front handle 102 on the front surface 902 of the CDU 100 in a view from the vertical direction (Z axis direction). Specifically, one of the two support portions 8c may be disposed on one side in the vertical direction (on the positive side of the Z axis) as compared with the front handle 102, and the other may be disposed on the other side in the vertical direction (on the negative side of the Z axis) as compared with the front handle 102. It is possible to stably rotate the panel 8 by the support portions 8c being located at the positions spaced apart from each other in the Z axis direction in this manner.

The support portions 8c may be provided at positions closer to the third surface 903 than the plurality of pump assemblies 4 on the second surface 902 of the housing 9. In this manner, the panel 8 is less likely to interfere during the insertion and removal operations of the pump assemblies 4 in a state where the panel 8 is at the second position as compared with a case where the support portions 8c are located between the plurality of pump assemblies 4 on the second surface 902. Therefore, workability at the time of insertion and removal of the pump assemblies 4 can be improved. Note that the support portions 8c may be provided at positions closer to the fourth surface 904 than the plurality of pump assemblies 4 on the second surface 902 of the housing 9.

As described above, the CDU 100 may include the plurality of pump assemblies 4. In this case, at least one pump assembly 4 from among the plurality of pump assemblies 4 may overlap with the panel 8 located at the first position in the insertion/removal direction (X axis direction) of the pump assembly 4.

It is possible to curb a decrease in flow rate of the refrigerant by operating other pump assemblies 4 even in a case where one pump assembly 4 has caused breakdown, by including the plurality of pump assemblies 4. Therefore, the CDU 100 is excellent in reliability. In addition, even in the case where the plurality of pump assemblies 4 that can be inserted into and pulled out from the housing 9 are provided, it is possible to dispose the pump assemblies 4 and the panel 8 even in a limited area since the panel 8 and the pump assemblies 4 can be disposed on the front surface 902.

Although FIG. 8 illustrates the example in which one pump assembly 4 from among the plurality of pump assemblies 4 and the panel 8 located at the first position overlap with each other in the insertion/removal direction (X axis direction) of the pump assembly 4, the number of pump assemblies 4 overlapping with the panel 8 is not limited thereto. A plurality of pump assemblies 4 and the panel 8 may overlap with each other in the insertion/removal direction of the pump assemblies 4. It is thus possible to secure a large area for the display 81.

The CDU 100 may include a plurality of panels 8. For example, the CDU 100 may include two panels 8. In this case, one panel 8 may be located rotatably between the first position and the second position by a support portion 8c provided at a position closer to the third surface 903 than the plurality of pump assemblies 4 on the second surface 902 of the housing 9. The other panel 8 may be located rotatably between the first position and the second position by a support portion 8c provided at a position closer to the fourth surface 904 than the plurality of pump assemblies 4 on the second surface 902. In a case where the two panels 8 are located at the first position, the two panels 8 may be located at positions at which the panels 8 overlap with all the plurality of pump assemblies 4. In other words, a so-called double door structure may be adopted. It is thus possible to secure a large area for the display 81.

As illustrated in FIGS. 8 and 11, the handles 41 of the pump assemblies 4 may overlap with the panel 8 in the insertion/removal direction (X axis direction) of the pump assemblies 4 in the state where the panel 8 is located at the first position. Specifically, the handles 41 may overlap with the second member 8b of the panel 8 in the insertion/removal direction (X axis direction) of the pump assemblies 4 in the state where the panel 8 is located at the first position. Also, a part of the handle side portions 412 of the handles 41 may overlap with the first member 8a of the panel 8 in the insertion/removal direction (X axis direction) of the pump assemblies 4 in the state where the panel 8 is located at the first position.

In this manner, it is possible to reduce erroneous operations of the handle 41 in the case where the panel 8 is at the first position by the handle 41 and the panel 8 being located at the overlapping positions in the insertion/removal direction (X axis direction) of the pump assemblies 4.

Specifically, each handle 41 may be adapted such that the two handle side portions 412 extends in the vertical direction (Z axis direction) and the handle operating portion 411 is located at a lower portion of the front surface 47 of the pump assembly 4 in the state where the panel 8 is located at the first position as illustrated in FIG. 11. In other words, the handle 41 may be at the fourth position corresponding to the lowered state.

In this state, the display 81 may be located between the two handle side portions 412 and above the handle operating portion 411.

According to such a configuration, it is possible to save the space of the housing 9 in the direction (X axis direction) along the insertion/removal direction of the pump assemblies 4 by the handles 41 located to project relative to the front surfaces 47 of the pump assemblies 4 and the display 81 being disposed so as not to overlap with each other.

As illustrated in FIG. 8, the panel 8 may include a plurality of through-holes 803 located below the display 81. Specifically, the second member 8b of the panel 8 may include a plurality of through-holes 803 located below the opening 801.

It is possible to send air to the pump assemblies 4 through the through-holes 803 even in the case where the panel 8 is at the first position, that is, in the state where the panel 8 covers the front surfaces 47 of the pump assemblies 4, by the panel 8 including the plurality of through-holes 803 in this manner.

As illustrated in FIGS. 8 and 11, the panel 8 may include a locking portion 83 that restricts movement of the panel 8 from the first position to the second position. Specifically, the locking portion 83 may be provided on the first member 8a of the panel 8. The locking portion 83 may be provided at a portion located further downward than the display 81 on the first member 8a of the panel 8.

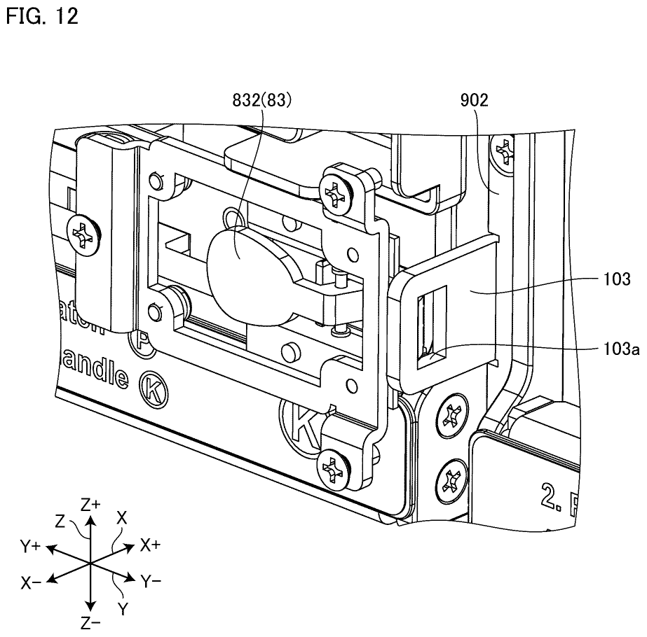

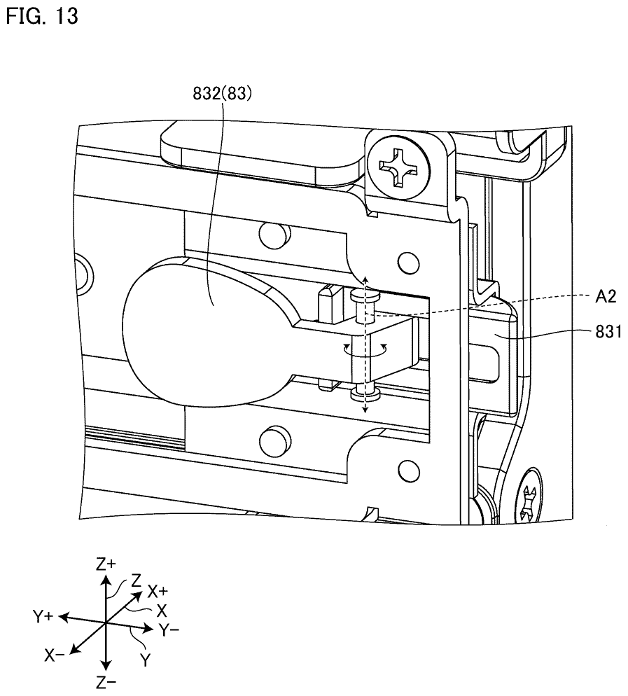

A configuration of the locking portion 83 according to the example embodiment will be described with reference to FIGS. 12 and 13. FIGS. 12 and 13 are perspective views illustrating the configuration of the locking portion 83 according to the example embodiment.

The locking portion 83 includes a slide bar 831, a spring (not illustrated), and an operation portion 832. The front surface 902 of the CDU 100 is provided with a plate member 103 projecting in a direction (the negative direction of the X axis) spaced apart from the housing 9, and a hole 103a into which the slide bar 831 can be inserted is formed in the plate member 103.

The slide bar 831 is slidable in an in-plane direction of the panel 8 and in a direction perpendicularly intersecting the rotation axis A1 (Y axis direction). The slide bar 831 is biased toward the hole 103a of the CDU 100 by a spring. The operation portion 832 is rotatable about a rotation axis A2 and is connected to the slide bar 831.

When the panel 8 is at the first position, one end portion of the slide bar 831 is inserted through the hole 103a by the spring, the slide bar 831 interferes with an inner wall of the hole 103a in this state, and the movement of the panel 8 from the first position to the second position is thus restricted.

When the operation portion 832 provided on the panel 8 is rotated about the rotation axis A2, the slide bar 831 slides in a direction spaced apart from the hole 103a (the negative direction of the Y axis) and is pulled out from the hole 103a, and the restriction state is thus released. This allows the panel 8 to rotate and move from the first position to the second position.

In this manner, it is possible to reduce movement of the panel 8 from the first position to the second position due to erroneous operations, by the panel 8 including the locking portion 83.

Note that the locking portion 83 is not limited to that illustrated in FIGS. 8 and 11 to 13. For example, the locking portion 83 may be a screw portion for screwing the panel 8 and the front surface 47 of the pump assembly 4. It is possible to reduce the movement of the panel 8 from the first position to the second position due to erroneous operations and to curb a situation in which the panel 8 moves at a timing not intended by the user and the user cannot check the display 81 in this case as well.

As for the panel 8, movement of the panel 8 from the second position to the first position may be restricted. For example, the movement of the panel 8 from the second position to the first position may be restricted by a so-called snap-fit structure.

Specifically, when the panel 3 is opened by a predetermined angle, that is, when the panel 8 is rotated from the first position to the second position, a projecting portion (not illustrated) provided on the panel 8 and a recessed portion (not illustrated) provided in the CDU 100 may interfere with each other, and the projecting portion may enter the recessed portion, such that the panel 8 may be fixed at the second position.

In this state, since the projecting portion hits the side wall of the recessed portion and the operation is suppressed even if it is attempted to rotate the panel 8 from the second position to the first position, it is not possible to rotate the panel 8 to the first position unless the user releases the restriction by pushing the projecting portion or the like.

Since the movement in the closing direction is curbed when the panel 8 is opened to insert or pull out the pump assembly 4 by restricting the movement of the panel 8 from the second position to the first position in this manner, it is possible to curb the panel 8 getting caught during the insertion and removal operations.

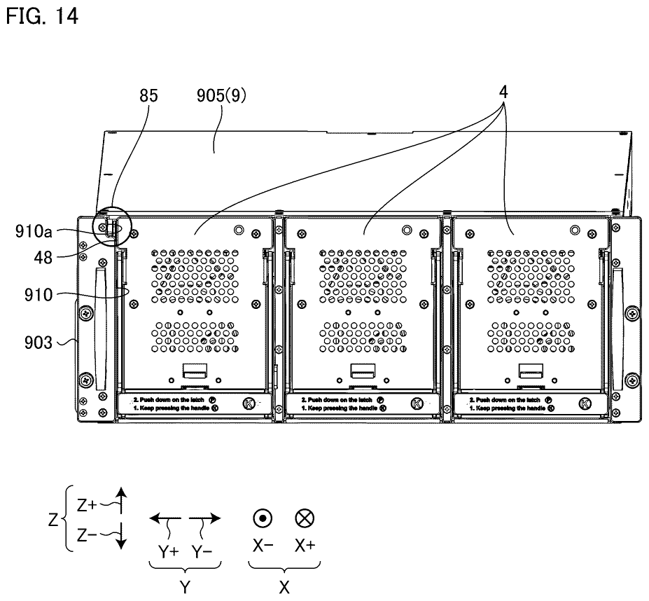

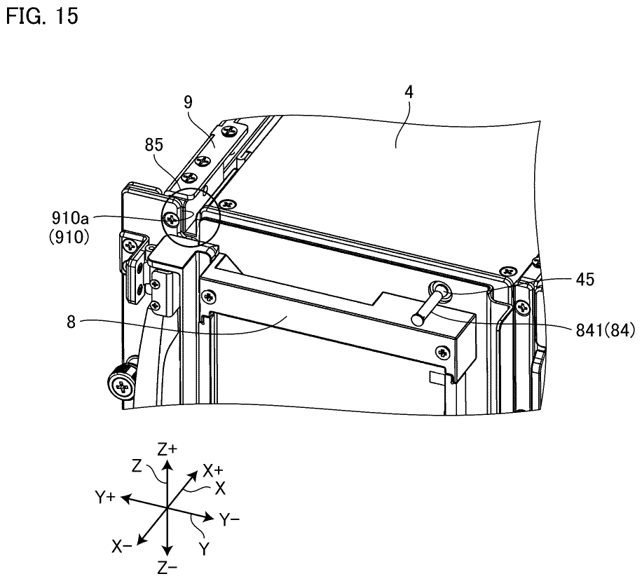

Next, a transmission portion 84 and a space 85 of the panel 8 according to the example embodiment will be described with reference to FIGS. 14 and 15. FIG. 14 is a front view of the CDU 100 according to the example embodiment. FIG. 15 is a perspective enlarged view illustrating the panel 8 and peripheral members thereof according to the example embodiment. Note that illustration of the first member 8a, the second member 8b, and the support portions 8c of the panel 8 are omitted in FIG. 14.

As illustrated in FIG. 15, the panel 8 may include the transmission portion 84. The transmission portion 84 overlaps with the indicator lamp 45 of the pump assembly 4 in the insertion/removal direction (X axis direction) of the pump assembly 4 in the state where the panel 8 is located at the first position. The transmission portion 84 transmits light from the indicator lamp 45.

Specifically, the transmission portion 84 may include a first transmission portion 841 that the first member 8a includes and a second transmission portion (not illustrated) that the second member 8b includes. The first transmission portion 841 may be, for example, a tubular member. The first transmission portion 841 extends in the direction perpendicularly intersecting the front surface 47 of the pump assembly 4 (X axis direction) in the state where the panel 8 is located at the first position. The through-hole of such a first transmission portion 841 and the indicator lamp 45 overlap with each other in the insertion/removal direction (X axis direction) of the pump assembly 4. The second transmission portion may be configured of a transparent or translucent member. For example, the second transmission portion may be formed of a material with a transmissive property, such as glass or acrylic. In this case, light of the indicator lamp 45 can be visually recognized by the user through the through-hole of the first transmission portion 841 and the second transmission portion.

Since the panel 8 includes the transmission portion 84 in this manner, the user can easily view the display of the indicator lamp 45 through the transmission portion 84 and can check the operating condition of the pump assembly 4 even in the case where the panel 8 is at the first position, that is, in the case where the front surface 47 of each pump assembly 4 is covered with the panel 8.

As illustrated in FIGS. 14 and 15, the panel 8 may include the space 85 located between the pump assemblies 4 and the housing 9. The space 85 is located between a first side surface 48 of the pump assembly 4 perpendicularly intersecting the insertion/removal direction (X axis direction) and a second side surface 910 of the housing 9 facing the first side surface 48. Specifically, the second side surface 910 includes a recessed portion 910a recessed from the second side surface 910 toward the third surface 903 at an end portion of the second side surface 910 on the side of the fifth surface 905. The space 85 is configured of such a recessed portion 910a and the first side surface 48. In this case, a wiring (not illustrated) connected to the display 81 may be located in the space 85. Such a wiring has, for example, one end connected to the rear surface of the display 81 and the other end connected to the control unit 6 (see FIG. 2). A signal from the control unit 6 is output to the display 81 via the wiring.

Arrangement of the wiring is facilitated as compared with a case where the space 85 is not provided, by the panel 8 including the space 85 between the pump assemblies 4 and the housing 9 and by the wiring being located in the space 85 in this manner.

In addition, there may be a space (not illustrated) between the first member 8a and the display 81. A wiring may be arranged in such a space. In this manner, arrangement of the wiring is facilitated, and it is possible to curb damage on the wiring as compared with a case where no space is provided.

Note that the example in which the panel 8 includes the first member 8a and the second member 8b has been described here, the configuration of the panel 8 is not limited thereto. The panel 8 may include only the first member 8a with the display 81. The panel 8 is similarly movable between the first position and the second position in this case as well, and it is thus possible to dispose the panel 8 and the pump assemblies 4 in a limited area.

In this case, the support portions 8c connected to the first member 8a may include extension portions (not illustrated) connecting the support portions 8c and the first member 8a. It is possible to provide a space between the first member 8a and the housing 9 with the extension portions and to thereby dispose the handle side portions 412 in the space between the first member 8a and the housing 9 without bringing the handle side portions 412 into contact with the display 81 in the state where the panel 8 is at the first position.

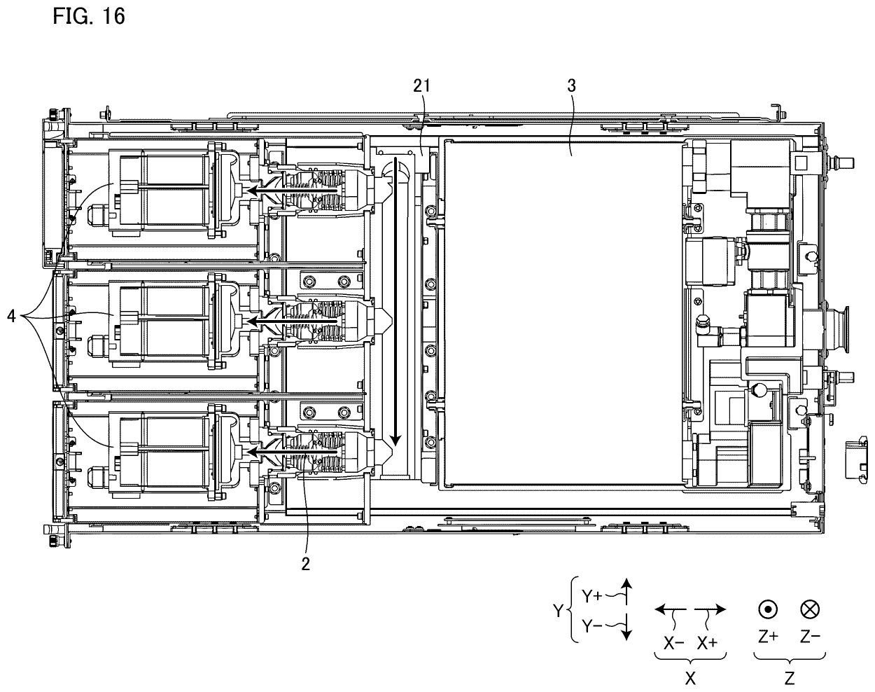

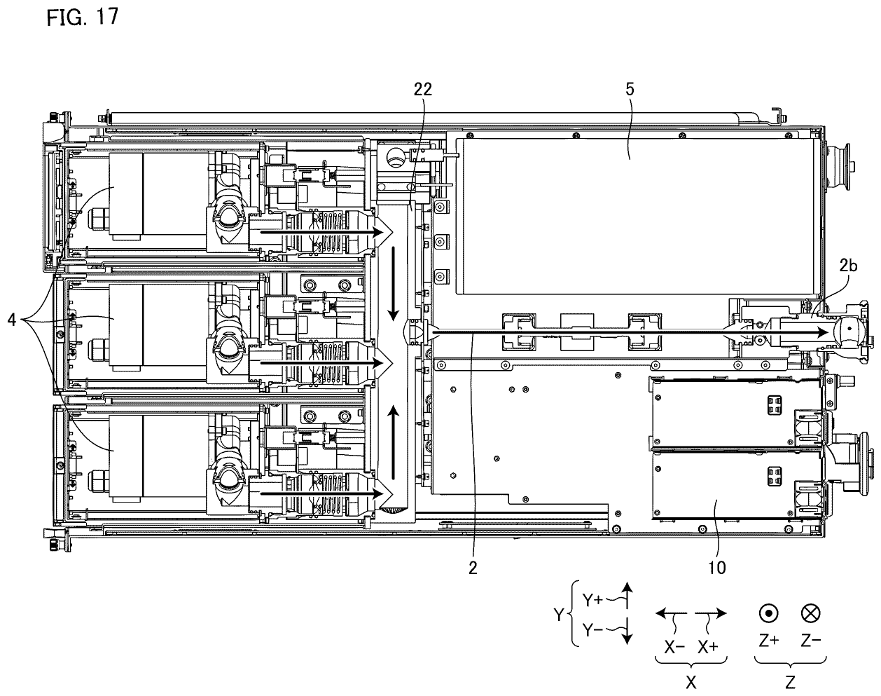

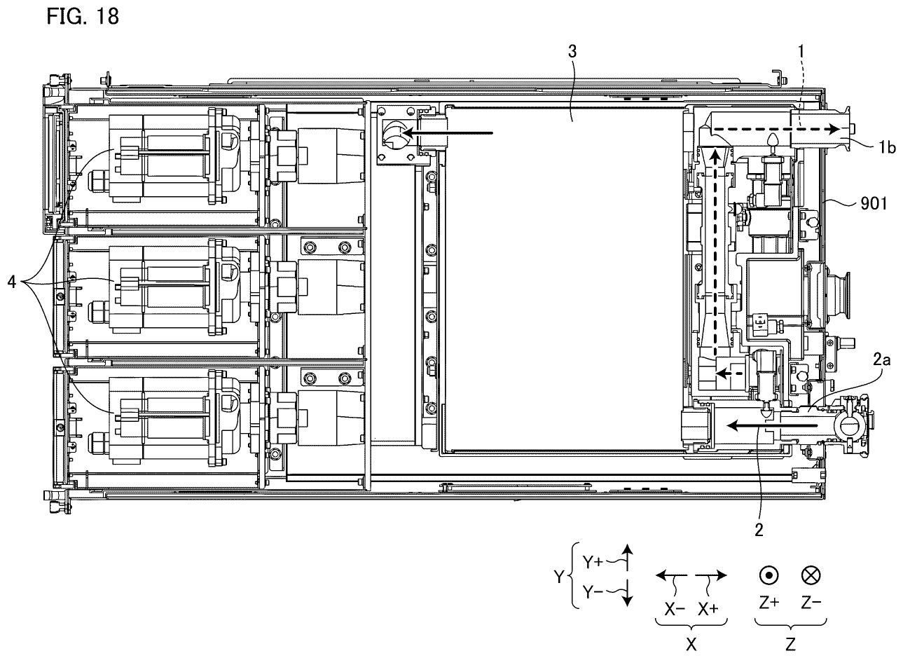

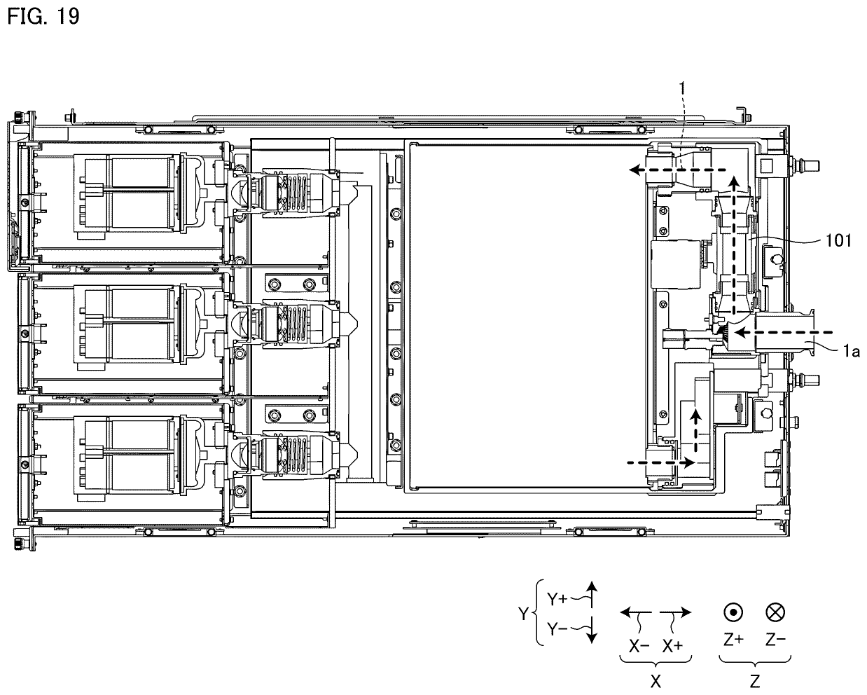

Next, the primary flow path 1 and the secondary flow path 2 according to the example embodiment will be described with reference to FIGS. 5 and 16 to 19. FIG. 16 is a sectional view along the line XVI-XVI in FIG. 4. FIG. 17 is a sectional view along the line XVII-XVII in FIG. 4. FIG. 18 is a sectional view along the line XVIII-XVIII in FIG. 4. FIG. 19 is a sectional view along the line XIX-XIX in FIG. 4. Note that the primary flow path 1 is illustrated by the dashed line arrows and the secondary flow path 2 is illustrated by the solid line arrows in FIGS. 16 to 19. The directions indicated by the arrows are the distribution directions of the refrigerant.

The primary refrigerant flowing through the primary flow path 1 flows in from the primary inlet port 1a provided in the rear surface 901 of the CDU 100, is distributed through the heat exchanger 3, and flows out from the primary outlet port 1b.

Note that in a modification example of the present embodiment, the primary flow path 1 may include a bypass flow path (not illustrated) that meets the primary outlet port 1b without flowing into the heat exchanger 3. It is possible to adjust the amount of primary refrigerant to flow into the heat exchanger 3 by including the bypass flow path, to thereby curb condensation due to an excessive decrease in temperature of the heat exchanger 3.

The secondary refrigerant distributed through the secondary flow path 2 flows in from the secondary inlet port 2a provided in the rear surface 901 of the CDU 100, flows into the heat exchanger 3, and then flows into each pump 42 via the distribution manifold 21. The secondary refrigerant pumped by the pump 42 is gathered by the collection manifold 22 and flows out from the secondary outlet port 2b. In the secondary flow path 2, a flow path from the heat exchanger 3 to the distribution manifold 21 is connected to the tank 5.

It is possible to connect the flow paths without providing individual flow paths from the heat exchanger 3 to each pump 42 by using the collection manifold 22 and the distribution manifold 21, and to thereby achieve a space saving effect.

As shown in FIGS. 16 and 17, the collection manifold 22 and the distribution manifold 21 are disposed so as to overlap with each other in the vertical direction (Z axis direction). The collection manifold 22 and the distribution manifold 21 are disposed between the heat exchanger 3 and the pump assemblies 4 in the X axis direction. With such an arrangement, a flow path tube of the secondary refrigerant flowing out of the heat exchanger 3 can be disposed in a space-saving manner, and the heat exchanger 3 can thus be enlarged.

As illustrated in FIGS. 16 and 17, the flow path extending from the tank 5, the power supplies 10, and the collection manifold 22 to the secondary outlet port 2b in the secondary flow path 2 is disposed on the heat exchanger 3. Therefore, the space in the horizontal direction (the X axis direction and the Y axis direction) in the CDU 100 can be allocated to the heat exchanger 3, the heat exchanger 3 can be enlarged, and the cooling performance of the CDU 100 can be improved.

As illustrated in FIG. 18, the flow path from the primary inlet port 1a to the heat exchanger 3 and the flow path from the heat exchanger 3 to the primary outlet port 1b in the primary flow path 1, and the flow path from the secondary inlet port 2a to the heat exchanger 3 in the secondary flow path 2 are disposed between the rear surface 901 and the heat exchanger 3 in the X axis direction. This leads to an effect that it is possible to dispose the flow path tubes for the primary flow path 1 and the secondary flow path 2 in a space-saving manner. Therefore, it is easy to increase the size of the heat exchanger 3, and the cooling performance can be improved.

As shown in FIGS. 18 and 19, the heat exchanger 3 includes the inlet port and the outlet port for the primary refrigerant and the inlet port for the secondary refrigerant on a side surface on one side in the X axis direction (on the positive side of the X axis) and includes the outlet port for the secondary refrigerant on a side surface on the other side in the X axis direction (on the negative side of the X axis). Also, the pump assemblies 4 are disposed on the other side in the X axis direction (on the negative side of the X axis) of the heat exchanger 3, and it is thus possible to improve an arrangement property of the primary flow path 1 and the secondary flow path 2.

As illustrated in FIG. 5, the CDU 100 can include the control valves 113, 232, 242, and 252 and the sensors 111, 112, 114 to 116, 211, 212, 214, and 215. In addition, sensors of types that are not illustrated can also be included at portions that are not illustrated.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A refrigerant circulation device comprising:
a housing that includes a flow path through which a refrigerant is distributable;
a pump assembly to be inserted into and pulled out from the housing; and
a panel that is on the housing and includes a display; wherein
the panel is movable between a first position at which the panel overlaps with the pump assembly and a second position at which the panel does not overlap with the pump assembly in an insertion/removal direction of the pump assembly.

2. The refrigerant circulation device according to claim 1, comprising:
a plurality of the pump assemblies; wherein
at least one of the plurality of pump assemblies overlaps with the panel located at the first position in the insertion/removal direction of the plurality of pump assemblies.

3. The refrigerant circulation device according to claim 2, wherein
the plurality of pump assemblies include handles;
the handles are on front surfaces along the insertion/removal direction of the plurality of pump assemblies and project in a direction away from the housing beyond the front surfaces; and
the handles overlap with the panel in the insertion/removal direction of the plurality of pump assemblies in a state where the panel is located at the first position.

4. The refrigerant circulation device according to claim 1, wherein the panel includes a locking portion to restrict movement of the panel from the first position to the second position.

5. The refrigerant circulation device according to claim 1, wherein movement of the panel from the second position to the first position of the panel is restricted.

6. The refrigerant circulation device according to claim 1, wherein
the pump assembly includes an indicator to display an operating condition of the pump assembly; and
the panel includes a transmission portion overlapping the indicator in the insertion/removal direction of the pump assembly in a state where the panel is located at the first position.

7. The refrigerant circulation device according to claim 1, wherein
the pump assembly includes a handle including two handle side portions that are located respectively on two side surfaces perpendicularly or substantially perpendicularly intersecting the insertion/removal direction of the pump assembly and a handle operating portion that is connected to one end portion of each of the two handle side portions and couples the two handle side portions;
the two handle side portions of the handle extend in a vertical direction and the handle operating portion is located at a lower portion of a front surface along the insertion/removal direction of the pump assembly in a state where the panel is located at the first position; and
the display is located between the two handle side portions and above the handle operating portion in the state where the panel is located above at the first position.

8. The refrigerant circulation device according to claim 1, wherein the panel includes a plurality of through-holes that are located below the display.

9. The refrigerant circulation device according to claim 1, wherein
the panel includes a space between a first side surface that perpendicularly or substantially perpendicularly intersects the insertion/removal direction of the pump assembly and a second side surface that opposes the first side surface of the housing; and
a wiring connected to the display is located in the space.

10. The refrigerant circulation device according to claim 1, wherein the display includes an operation surface that receives an operation by a user.
